(19) United States
(12) Patent Application Publication
(10) Pub. No.: US 2009/0322210 A1
(43) Pub. Date: Dec. 31, 2009

(54) Organic electroluminescent element substrate, and organic electroluminescent element and the manufacturing method

(76) Inventor: Masahiro Yokoo, Tokyo (JP)

Correspondence Address: SQUIRE, SANDERS & DEMPSEY L.L.P., 1 MARITIME PLAZA, SUITE 300, SAN FRANCISCO, CA, 94111, US

(21) Appl. No.: 11/516,352

(22) Filed: Sep. 6, 2006

(30) Foreign Application Priority Data
Sep. 27, 2005 (JP) 2005-279608

(51) Int. Cl. H01J 1/62; H01L 21/28

(52) U.S. Cl. 313/504; 438/29; 257/E21.158

(57) ABSTRACT

The present invention is directed to an organic electroluminescent element of good display characteristic without being contaminated with air in the case that a sealing substrate is affixed to an entire surface of the effective pixels of an organic electroluminescent element substrate by an adhesive. An organic electroluminescent element substrate includes a substrate, pixel electrodes formed over the substrate, an organic luminescence medium layer including an organic luminescent layer on the pixel electrodes which emits different color light, and opposed electrodes wherein the organic luminescence medium layer is between the pixel electrodes and the opposed electrodes, wherein the organic electroluminescent element substrate has partition wall(s), and wherein difference of height in effective pixels of the organic electroluminescent element substrate is less than 1 μm.

### CROSS REFERENCE

This application claims priority to Japanese application number 2005-279608, filed on Sep. 27, 2005, which is incorporated by reference.

### BACKGROUND OF THE INVENTION

1. Field of the Invention

The present invention is related to an organic electroluminescent element substrate which can be used in display units such as an information display terminal. The present invention is also directed to a method of manufacturing an organic electroluminescent element substrate.

The present invention is related to organic electroluminescent element of the top emission type wherein a direction that light comes out of is an opposite direction of a substrate.

2. Description of the Related Art

An organic electroluminescent element is explained below.

A thin film including a luminescent material is sandwiched between a cathode and an anode. Electron and hole are poured into the thin film. Recombination of the electron and the hole occurs. Excitons are produced in this recombination. The organic electroluminescent element emits light by using emission of light (fluorescence/phosphorescence) when the excitons are deactivated.

Character of this organic electroluminescent element is explained below.

High intensity plane emission of about 100-100000 cd/m² occurs when low voltage of less than or equal to 10V is applied to the organic electroluminescent element. In addition, by selecting a type of luminescent materials, luminescence from blue to redness is possible.

The organic electroluminescent element attracts attention as an element which can realize a cheap large area full color display device (Institute of Electronics, Information and Communication Engineers technical bulletin, Vol. 89, No. 106, Page 49, 1989). According to the bulletin, bright luminescence of redness (R), green (G) and blue (B) was achieved by using organic coloring matters emitting strong fluorescence in luminous layers. It is thought that a high intensity full color display was able to be realized because the organic coloring matters which emitted fluorescence and was little pin hole fault in a thin-film state was used.

Even more particularly, in a patent document (Japanese Patent Laid-Open No. 5-78655 Official Gazette), a high intensity full color device was proposed. In the proposal, a thin layer comprising mixture of organic charge material and organic luminescent material was formed, and concentration quenching was prevented, and range of choice of luminescent materials was broadened.

As for the organic electroluminescent material, two kinds of a low molecular system material and a polymeric material are exemplified. The low molecular based material layer is generally formed by an evaporation method. However, from aspects of an evaporation device and an alignment accuracy corresponding to a large-scale substrate, upsizing is difficult.

Thus, recently, polymeric materials are applied to the organic luminescent material, and the organic luminescent material is dissolved in solvent in order to make ink, and a method how thin film is formed by a wet coating method with the use of the ink is tested. For a wet coating method to form thin film, a spin coat method, a bar coat method, an extrusion coat method and a dip coat method are exemplified. However, in these wet coating methods, it is difficult to do patterning highly minutely and to apply three colors of RGB separately in order to use the organic electroluminescent element as a display unit. It is thought that thin film formation by a printing method which is good at patterning separately is more effective. As attempt of the printing methods, a method by an ink jet printing (Japanese Patent Laid-Open No. 10-012377 Official Gazette) and a method by relief printing (Japanese Patent Laid-Open No. 2001-155858 Official Gazette) are proposed.

In addition, depending on a difference of the direction that light comes out, the organic electroluminescent element is divided into a bottom emission type and a top emission type. As for the bottom emission type, light goes out of a substrate side. As for the top emission type, light goes out of an opposite side of the substrate side.

When ink is made of an organic luminescent material, and an organic luminous layer emitting different light in each pixel is formed, it is necessary to provide a partition wall between pixel electrodes for the purpose of coating an anode end part for preventing short circuit and for the purpose of preventing different-colored ink from mixing. However, an organic luminescent material is generally hard to dissolve in a solvent. When ink is made by means of dissolution of an organic luminescent material with a solvent, concentration of an organic luminescent material is about 1-5 wt % and is low. By means of using such an ink, ink is applied to pixel areas sectioned by the partition wall. It is necessary to supply a large amount of ink in order to supply enough organic luminescent material in each pixel. So sufficiently-high partition wall is necessary to prevent the ink from overflowing to a neighboring pixel.

In addition, in the organic electroluminescent element substrate including a pixel electrode, an organic luminescence media layer including an organic luminous layer and an opposed electrode on a substrate, sealing is performed to prevent entry of water and oxygen into the element substrate internal, particularly the organic luminous layer.

Sealing in the case of bottom emission type organic electroluminescent element is explained below. A glass or metal cap (a sealing cap) with concavity corresponding to effective pixels part used for display is used. Sealing is performed by affixing a sealing cap to a penumbra of effective pixels of an organic electroluminescent element substrate by means of adhesive. An organic electroluminescent element is formed in this way. In addition, drying agent or oxygen absorbent may be included in inside of sealing cap.

In the case of top emission type, an organic electroluminescent element substrate is sealed by using sealing substrate having translucency. For this case, if an adhesive having translucency is used, a sealing substrate having translucency can be affixed to a whole area of a surface for the opposed electrode formation of an organic electroluminescent element substrate, so the opposed electrode formation of an organic electroluminescent element substrate or a whole area of sealing substrate can be provided with an inorganic thin film formed by vacuum film forming method such as evaporation, as water vapor barrier layer for the purpose of preventing entry of moisture to inside of the element substrate if necessary.

In the case that a sealing substrate are affixed to a whole area of opposed electrode forming face of an organic electroluminescent element substrate by means of an adhesive, there can be a problem that the element substrate might be contaminated with air due to unevenness of an organic electroluminescent element substrate surface. Particularly in the case that configuration of an organic electroluminescent element substrate comprises a partition wall, this problem occurs. Even more particularly, intrusion of air is easy to occur near a pixel contributing to display because a partition wall is usually formed to section a pixel. Therefore, problems that affect visibility and luminescence property become worse over time. By means of thickening adhesive or steam barrier layer, air contamination can be prevented to some extent. However, in the case of an organic electroluminescent element of top emission type, an adhesive and a water vapor barrier layer are reduced as thin as possible. And decreasing of an optical transmission rate by these layers should be controlled as much as possible. Therefore, this means for solving the problems is against the demand. In the case that a steam barrier layer is formed on a whole area of an opposed electrode of an organic electroluminescent element substrate to cover unevenness of an organic electroluminescent element substrate, if film thickness of a steam barrier layer is large, there is the problem which crack is easy to occur in a steam barrier layer at the uneven part.

### SUMMARY OF THE INVENTION

An object of the present invention is to provide an organic electroluminescent element of a good display characteristic without being contaminated with air in the case that a sealing substrate is affixed to an entire surface of the effective pixels of an organic electroluminescent element substrate by adhesive. An organic electroluminescent element substrate is provided including a substrate, pixel electrode(s) formed on the substrate, an organic luminescence medium layer including an organic luminescent layer on the pixel electrode(s) which emits different color light and opposed electrode(s) wherein the organic luminescence medium layer are sandwiched between the pixel electrode(s) and the opposed electrode(s), wherein the organic electroluminescent element substrate has partition wall(s), and wherein difference of height in effective pixels of the organic electroluminescent element substrate is lower than 1 μm.

### BRIEF DESCRIPTION OF DRAWINGS

FIG. 1 is a cross-section of an organic electroluminescent element of an embodiment of the present invention.

FIG. 2 is a cross-section of organic electroluminescent element substrate of an embodiment of the present invention.

FIGS. 3A, 3B, 3C, and 3D are schematic views that show an intaglio offset printing machine and an intaglio offset-printing process of an embodiment of the present invention.

FIGS. 4A, 4B, 4C and 4D are schematic views that show a letterpress reversing offset printing apparatus and a letterpress reversing offset printing process of an embodiment of the present invention.

FIGS. 5A, 5B, 5C and 5D are schematic views which show a relief printing apparatus and a relief printing process of an embodiment of the present invention.

In these drawings, 1 is a substrate; 2 is a pixel electrode; 3 is a hole transport layer; 41 is a red organic luminescent layer; 42 is a green organic luminescent layer; 43 is a blue organic luminescent layer; 5 is an opposed electrode; 6 is a barrier layer; 7 is an adhesive; 8 is a sealing substrate; 11 is a main body frame; 12 is a blanket cylinder; 13 is a blanket; 14 is a printing stage; 15 is an intaglio; 16 is a substrate; 17 is ink; 18 is a doctor blade; 19 is a relief printing plate; 21 is an anilox roll; 22 is a printing cylinder; 23 is a relief printing plate; and 24 is an ink feed means.

### DESCRIPTION OF THE PREFERRED EMBODIMENTS

An organic electroluminescent element of the present invention is explained. The organic electroluminescent element and the manufacturing method concerning the present invention are not limited to the embodiment explained below. In addition, the example which this detailed description of the preferred embodiment is applied to an organic electroluminescent display panel of passive matrix driving type is explained as follows.

For a driving method of an organic electroluminescent element, there are passive matrix method and active matrix method, but an organic electroluminescent element in detailed description of the preferred embodiment can be applied to both passive matrix method and active matrix method.

In addition, the present invention can be applied to specific delta array among active matrix methods.

In addition, as for emission takeout direction, either of substrate side direction or sealing side direction can be achieved.

In present specification, a member having a substrate, pixel electrodes on a substrate, an organic luminescence media layer including an organic luminous layer and an opposed electrode is defined as “an organic electroluminescent element substrate”.

In addition, a member having “the organic electroluminescent element substrate”, a steam barrier layer and the like formed on “the organic electroluminescent element substrate” if necessary and a sealing substrate which is put on “the organic electroluminescent element substrate” by adhesive is defined as “an organic electroluminescent element”.

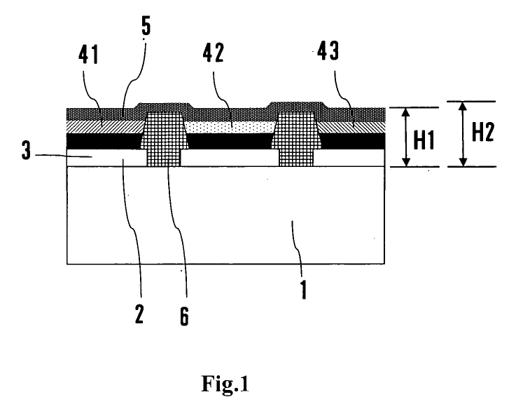

A cross-sectional figure of an organic electroluminescent element substrate of an embodiment of the present invention is shown in FIG. 1. In addition, an effective pixel in the present invention means both an area where electrodes facing each other and an organic luminescence media layer between the electrodes are formed on an organic electroluminescent element substrate, and an area where partition wall sectioning the electrodes and the organic luminescence media layer is formed.

In other words an effective pixel means a part contributing to display of information or luminescence as a display unit after an organic electroluminescent element is manufactured.

In addition, this organic luminescence media layer includes at least an organic luminous layer.

An organic electroluminescent element of the present invention has pixel electrodes 2 on substrate 1, and partition wall 6 is formed between pixel electrodes 2. In addition, the organic luminescence media layers including organic luminous layers (41, 42, and 43) are formed on pixel electrodes 2 sectioned by partition wall 6. An opposed electrode 5 is formed on an organic luminescence media layer. In addition, in FIG. 1, the opposed electrode 5 is formed on a whole area where an organic luminescence media layer is formed, while patterning of the opposed electrode 5 is not performed. Therefore, the opposed electrode 5 is also formed on the partition wall 6. However, if necessary, patterning of the opposed electrode 5 may be performed, and the opposed electrode 5 may not formed on partition wall 6.

An organic luminescence media layer may include monolayer of organic luminous layer. A hole transport layer, a hole injection layer, an electronic transport layer and an electron injection layer are appropriately formed in the organic luminescence media layer other than organic luminous layer for the purpose of assisting luminescence in organic luminous layer.

A structure shown in FIG. 1 is a double-layered structure which the organic luminescence media layer has a hole transport layer 3 and an organic luminous layer (41, 42, 43). And organic luminous layers including organic luminescent materials emitting lights of different colors such as RGB are placed in each pixel.

FIG. 1 shows a cross section drawing wherein an organic electroluminescent element substrate with stripe-shaped red organic luminous layer (41), green organic luminous layer (42) and blue organic luminous layer (43) is cut along a direction crossing the stripe-shape.

In the present invention, difference of height in the effective pixels of an organic electroluminescent element substrate means difference of height in a part where there are pixels contributing to display of information as a display unit in an organic electroluminescent element substrate. Practically the difference of height in the effective pixels of an organic electroluminescent element substrate means a difference between the height (H1) in the area of a pixel electrode sectioned by a partition wall and the height (H2) in the area where a partition wall is formed.

In an organic electroluminescent element substrate of the present invention, height of the partition wall which sections each pixel and prevents mixed of colors is roughly equal to height which is the sum of thickness of a pixel electrode and thickness of an organic luminescence media layer. In some cases, the height of the partition wall may be height which is the sum of thickness of a pixel electrode, thickness of an organic luminescence media layer and thickness of an opposed electrode.

By means of setting partition wall of such a height, difference of height in an effective pixel is adjusted to be lower than 1 μm.

In addition, preferably difference of height in effective pixels is lower than 0.3 μm. When difference of height in effective pixels is more than 1 μm, an organic electroluminescent element may be contaminated with air at adhesion with a sealing substrate due to unevenness of an organic electroluminescent element substrate.

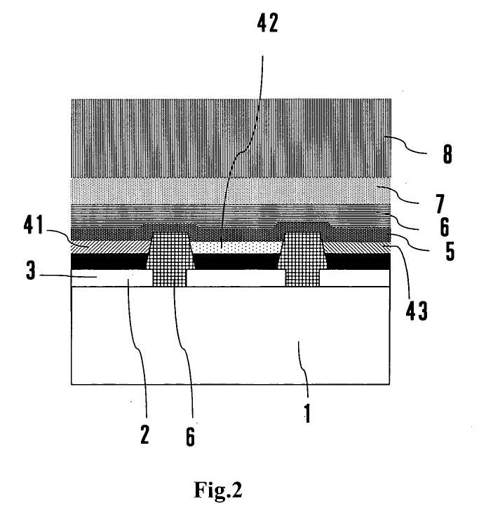

A cross-sectional figure of organic electroluminescent element of an embodiment of the present invention is shown in FIG. 2.

If necessary, a steam barrier layer and an oxygen barrier layer are formed in an organic electroluminescent element substrate that pixel electrodes, an organic luminescence media layer and an opposed electrode are formed on a substrate. And an organic electroluminescent element substrate is affixed to a sealing substrate by adhesive.

A whole area of the effective pixels included in an organic electroluminescent element substrate is covered with adhesive, and is bonded to a sealing substrate. In addition, a steam barrier layer and an oxygen barrier layer may be formed on the sealing substrate side.

In addition, the barrier layer for steam, oxygen and the like may be a multi-layer structure.

A manufacturing method of an organic electroluminescent element substrate and organic electroluminescent element of the present invention is explained next.

As a substrate in the present invention, any kind of substrate can be used provided that a substrate has insulating property. In addition, it is desirable that a substrate has enough strength to support pixel electrodes, an organic luminescence media layer and an opposed electrode formed on the substrate.

In the case of an organic electroluminescent element of bottom emission method, it is necessary to use a clear substrate. By way of example only, a glass substrate and a film or sheet made of plastic can be used.

If a film made of flexible plastic is used, manufacture of an organic electroluminescent element by reel up method is enabled. Therefore, inexpensive element can be obtained. For example, for the plastic which can be used as a film-shaped substrate, poly ethylene terephthalate, polypropylene, cyclo olefin polymers, polyamide, polyethersulfone, poly methyl methacrylate and polycarbonate can be used.

In addition, it is desirable that moisture adsorbed in inside and surface of these substrates is reduced as much as possible by heat-treating beforehand. In addition, it is desirable that a substrate is used after surface treatment such as ultrasonic cleaning, corona discharge treatment, plasma treatment and UV ozone treatment is performed on the substrate in order to improve adhesiveness of a substrate and a material formed on the substrate. According to the material formed on the substrate, a kind of the surface treatment is selected.

In addition, by means of forming thin film transistor (TFT) on these substrates, a driving substrate of active matrix method can be made.

For material of TFT, even organic TFT such as polythiophene, polyaniline, copper phthalocyanine or perylenes is preferable, and even TFT of amorphous silicon and a polySi is also preferable.

The present invention can be applied to organic electroluminescent display devices of both passive matrix method and active matrix method.

In passive matrix method, a pixel electrode and an opposed electrode are formed in the shape of stripe respectively. A pixel electrode is perpendicular to an opposed electrode. In each intersection point, it emits light.

In addition, in active matrix method, so-called thin film transistor (TFT) substrate on which transistor is formed in each pixel electrode is used. The element in active matrix method emits light by each of the respective pixels.

On this substrate, pixel electrodes are formed. When pixel electrodes are used as anode, the following material can be used as material of pixel electrodes: metal complex oxide such as ITO (indium tin complex oxide), IZO (indium zinc complex oxide) and zinc aluminium complex oxide; metallic substances such as chromium, gold and platinum; particle diffusion film which finely divided particles of these metallic oxides and metallic substances are dispersed in epoxy resin or acrylic resin; and monolayer and multilayer comprising above described materials.

In the case of top emission method, a light-reflecting material is mainly used.

Dry coating method can be used as a formation method of pixel electrodes. By way of example only, resistance heating evaporation method, electron-beam evaporation technique, reactivity evaporation method, ion plating method and sputtering method can be used.

By way of example only, pixel electrodes can be made as follows:

A photoresist is applied to a metallic oxide film formed by vacuum deposition. Exposure/developing are performed. Wet etching or dry etching is performed. In this way pattern-shaped pixel electrodes can be formed.

In addition, metal such as copper, chromium, aluminium, titanium or these laminated materials can be added as a supporting electrode to pixel electrodes partially to reduce electrical resistance.

Next, partition wall is formed between pixel electrodes.

A photosensitive resin can be used as formation material of partition wall. Both a positive type resist and a negative type resist can be used. Commercial material can be used. Formation material of partition wall has to have insulating properties. When partition wall does not have insulating properties, adjacent electrodes short-circuit through partition wall. Therefore, display defects occur. By way of example only, material such as polyimide system, an acryl resin system or a novolak resin system can be used. In addition, light shielding materials such as carbon particle may be included in the above described materials for partition wall formation for the purpose of improving display quality of organic electroluminescent element.

Height of partition wall is a factor determining difference of height in effective pixels of an organic electroluminescent element substrate of the present invention. It is necessary for the height of the partition wall to be low and is necessary not to form unnecessary layer on the partition wall in order to set the difference of height between a highest part and a lowest part in effective pixels of an organic electroluminescent element substrate to be lower than 1 μm.

In addition, it is desirable that the layer formed on each pixel sectioned by the partition wall is formed thinly and uniformly.

Therefore, difference of height between each pixel electrode and partition wall should be lower than 1.5 μm when thickness of an organic luminescence media layer and an opposed electrode formed later is taken into consideration.

An organic luminescence media layer is formed next. An organic luminescence media layer may include only a single layer of an organic luminous layer. An organic luminescence media layer may have a laminated structure combined with an organic luminous layer and a layer to assist luminescence such as a hole transport layer, a hole injection layer, an electron transport layer and an electron injection layer. In addition, the layer which assists luminescence such as a hole transport layer, a hole injection layer, an electron transport layer and an electron injection layer is selected appropriately.

An organic luminescent layer is a layer including organic luminescent material which emits light when an electric current flows.

The organic luminescent material can include low molecular type organic luminescent material. Representative embodiments of low molecular type luminescent materials include the following:

9,10-diaryl anthracenes, pyrene, coronene, perylene, rubrene, 1,1,4,4-tetra phenylbutadiene, tris(8-quinolinolate) aluminium complex, tris(4-carbinyl-8-quinolinolate) aluminium complex, bis(8-quinolinolate) zinc complex, tris(4-carbinyl-5-trifluoromethyl-8-quinolinolate) aluminium complex, tris(4-carbinyl-5-cyano-8-quinolinolate) aluminium complex, bis(2-carbinyl-5-trifluoromethyl-8-quinolinolate) [4-(4-cyanophenyl)phenolate]aluminium complex, bis(2-carbinyl-5-cyano-8-quinolinolate) [4-(4-cyanophenyl)phenolate]aluminium complex, tris(8-quinolinolate) scandium complex, bis[8-(para-tosyl)aminoquinoline]zinc complex and cadmium complex, 1,2,3,4-tetraphenylcyclopentadiene, the pentaphenyl cyclopentadiene, and poly-2,5-diheptyloxi-para-phenylenevinylene.

The materials which the following low molecular material is dispersed in polymer materials can be used: coumarin type fluorescent substance, the perylene type fluorescent substance, the pyran type fluorescent substance, the anthrone type fluorescent substance, the porphyrin type fluorescent substance, the quinacridon type fluorescent substance, N,N′-dialkyl displacement quinacridon type fluorescent substance, the naphthalimido type fluorescent substance, N,N′-diaryl displacement pyrrolo pyrrole series fluorescent substance, and phosphorescence fluor such as Ir chelate.

As the above-mentioned polymer materials, polystyrene, polymethyl methacrylate polyvinylcarbazole and the like can be used. In addition, poly arylene type, poly arylenevinylene type, poly fluorene, polyphenylene vinylene, polyparaphenylene vinylene, polythiophene, and polyspiro can be used as polymer solvent.

The material which inter-polymerization of the low molecular material with these high polymer materials is done, the material which low molecular system luminescent material is scattered in polymer materials or existing luminescent material can be also used.

Representative examples of a hole transport material, comprising a hole transport layer, include copper phthalocyanine, metallophthalocyanine such as tetra(t-butyl) copper phthalocyanine, metal-free phthalocyanine, quinacridon chemical compound, aromatic amine type low molecular hole injection transportation material such as N,N′-di(1-naphthyl)-N,N′-diphenyl-1,1′-biphenyl-4,4′-diamine, 1,1-bis(4-di-p-tolylamino phenyl)cyclohexane, N, N′-diphenyl-N,N′-bis(3-methylphenyl)-1,1′-biphenyl-4,4′-diamine, macromolecule hole transport materials such as polyaniline (PANI), polythiophene, polyvinylcarbazole, mixture with poly(3,4-ethylenedioxy thiophene) (PEDOT) and polystyrene sulfonate, polythiophene oligomer material, and other existing hole transport materials.

Representative examples of an electron transport material include 2-(4-Biphenyl-il)-5-(4-t-butylphenyl)-1,3,4-oxadiazole, 2,5-bis(1-naphthyl)-1,3,4-oxadiazole, oxadiazoles, bis(10-hydroxybenzo[h]quinolinate) beryllium complex, triazole compound, and combinations thereof.

Ink is made by adding solvent and necessary additive to functional material included in the respective layers.

For solvent dissolving functional material, the following solvent can be used: toluene, dimethylbenzene, acetone, anisole, methyl ethyl ketone, methyl isobutyl ketone, cyclohexanone, dichloromethane dichloroethane, chloroform, ethyl acetate, ethanol, methanol, 2-methoxy ethanol, 2-ethoxyethanol, 2-butoxyethanol, 2-ethyl ethoxy acetate, 2-butoxy ethyl acetate, 2-methoxy ethyl ether, 2-ethoxy ethyl ether, 2-(2-ethoxy ethoxy)ethanol, 2-(2-butoxy ethoxy)ethanol, 2-(2′ethoxy ethoxy)ethyl acetate, 2-(2-butoxy ethoxy)ethyl acetate, glycol, ethylene glycol, propylene glycol monomethyl ether, propylene glycol monomethyl ether acetate, diethylene glycol dimethyl ether, tetrahydrofuran and water.

Only single solvent may be used. Mixed solvent may be used.

Above all, when ink of a luminescent material is made, aromatic organic solvent such as toluene, dimethylbenzene and anisole is preferred from the viewpoint of solubility of a luminescent material.

Difference of height in the effective pixels is suppressed within 1 μm to prevent intrusion of air in the case of sealing of an organic electroluminescent element substrate of the present invention.

When such an organic electroluminescent element substrate includes partition wall, it is desirable that height of the partition wall from pixel electrodes is less than 1.5 μm. When height of partition wall is more than 1.5 μm, even if an organic luminous layer and an opposed electrode are formed in each pixel afterwards, it is difficult that difference between height of those parts (an organic luminous layer and an opposed electrode) and height of the upper part of partition wall can be shortened within 1 μm.

The height of the partition wall required here is too low in comparison with the height of the partition wall sectioning pixel electrode in the case of formation of organic light emitting layer by ink jet method. In ink jet method, ink is discharged from a head and drops on a substrate. Therefore, spreading of ink, error of location accuracy and a bounce of ink can occur. Therefore ink flies over partition wall when light emitting layer is formed in each pixel areas. And color mixture between adjoining pixels occurs.

Thus a printing method is preferable to form light emitting layer of an organic electroluminescent element substrate of the present invention. Offset printing and relief printing can be desirably used as a formation method of light emitting layer.

Offset printing is explained below. Ink pattern is once formed on a transfer support comprised rubber having ink separating property as referred to as a blanket. The ink pattern is transferred to a substrate. As for the ink pattern formed on the blanket, one part of ink solvent is absorbed by the blanket, and the ink pattern becomes semidried. Therefore, pattern configuration and film thickness of ink are easy to be controlled.

For such an offset printing, intaglio offset printing and relief reversal offset printing are exemplified. These printing methods are different in a formation method of ink pattern on the blanket.

Relief printing method is explained below. Ink is supplied from an ink chamber to an anilox roll. Excess ink is removed by a doctor blade. An anilox roll touches a relief printing plate comprising rubber plate or resin plate afterwards. In that case, desired amount of ink moves from an anilox roll to a relief printing plate. Ink transfers from a relief printing plate to a substrate afterwards. In this time, printing pressure between a relief printing plate and a substrate is adjusted to a small level. Then even if partition wall is low, jumping of ink over partition wall can be prevented.

By means of such a manufacturing method by offset printing and relief printing method, even if height of the partition of an organic electroluminescent element substrate is set very low, color mixture between adjoining pixels can be prevented without ink spreading at the time of transferring of ink to a substrate.

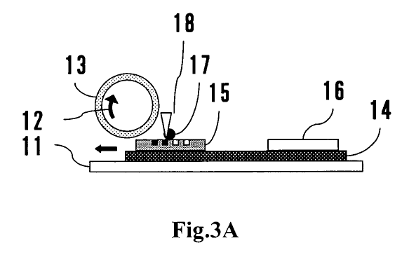

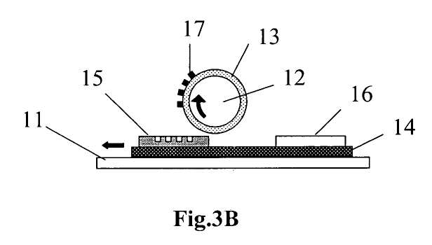

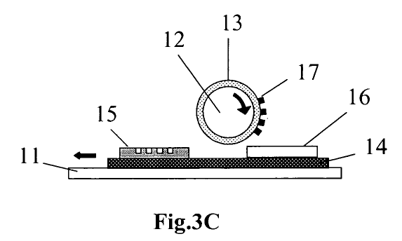

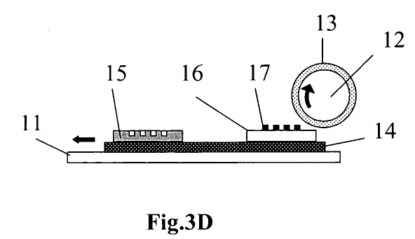

As an example of the printing method that can be used in the present invention, a printing process with intaglio off-set printing device is explained in detail in FIGS. 3A-3D.

FIGS. 3A-3D are the schematic views which show intaglio off-set printing device and intaglio off-set printing process. In FIG. 3B, blanket 13 is mounted around blanket cylinder 12 in upside of body flame 11. In addition, 14 is a printing stage. Intaglio 15 which is an original plate, or substrate 16 on which pixel electrodes are formed is fixed to printing stage 14 at the time of printing. Blanket cylinder 12 is installed rotatably. Intaglio 15 can touch blanket 13 by constant pressure force. Substrate 16 can touch blanket 13 by constant pressure force. In addition, printing stage 14 can move in a uniaxial direction. In addition, 17 shown in FIG. 3 is an organic luminescence ink (hereinafter referred to as ink). 18 is a doctor blade scraping excess ink from intaglio 15.

Intaglio 15 is fixed on printing stage 14. Ink 17 is supplied on intaglio 15 by the ink feed means that is not illustrated. Excess ink is removed by a doctor blade in accordance with movement of printing stage 14. And pattern part of intaglio 15 is filled with ink 17 (FIG. 3A). While printing stage 14 further moves, blanket cylinder 12 rotates. Then the ink which is filled in pattern part of intaglio 15 is received on blanket 13. Therefore, ink pattern is obtained on a blanket (FIG. 3B). Next, while printing stage 14 moves, blanket cylinder 12 rotates. Then ink pattern on blanket is transferred to substrate 16. Printing is finished in this way (FIGS. 3C, 3D).

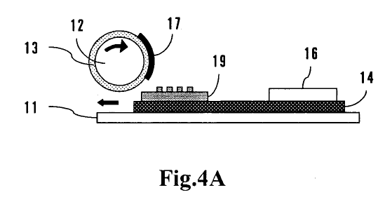

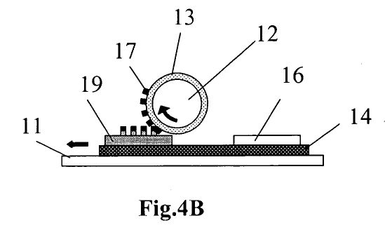

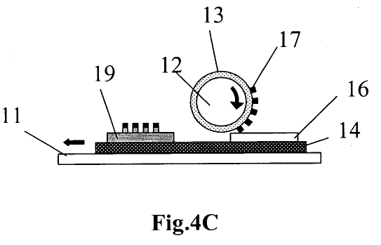

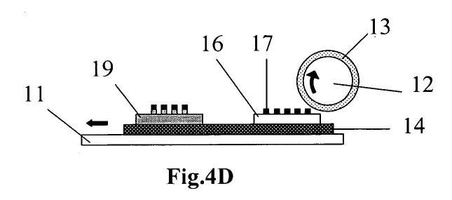

As the second example of the printing method that can be used in the present invention, a printing process with relief reversal offset printing machine is described in detail in FIGS. 4A-4D.

FIGS. 4A-4D are the schematic views which show a relief reversal offset printing machine and a relief reversal offset printing process. Blanket 13 is mounted around blanket cylinder 12 in upside of main body flame 11. In addition, relief printing plate 19 that is an original plate, or substrate 16 on which pixel electrodes are formed is fixed to printing stage 14 at the time of printing. Blanket cylinder 12 is installed rotatably. Blanket 13 can touch relief printing plate 19 with constant pressure. Blanket 13 can touch substrate 16 with constant pressure. In addition, printing stage 14 can move in an uniaxial direction. In addition, 17 shown in FIG. 4 is ink.

Relief printing plate 19 is fixed on printing stage 14. Film of ink 17 is applied to blanket 13 uniformly beforehand by the ink feed means that is not illustrated. (FIG. 4A) As an ink feed means, a curtain coat, a bar coat, a wire coat and a slit coat can be used. While print stage 14 moves, a blanket cylinder rotates. Then a pattern part of relief printing 19 having a negative pattern of a desired pattern touches an ink layer on blanket 13. Then an unnecessary part corresponding to the pattern part is removed. And desired pattern-shaped ink is left on a blanket (FIG. 4B). Then, while print stage 14 moves, a blanket cylinder rotates. Then an ink pattern left on a blanket is transferred to substrate 16. Print is finished in this way (FIGS. 4C, 4D).

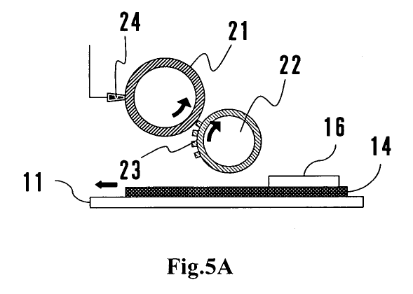

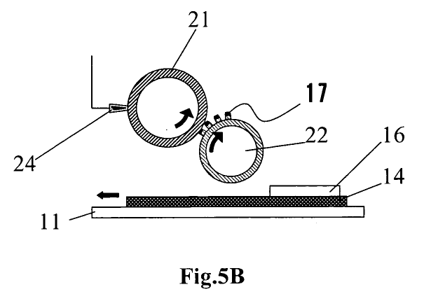

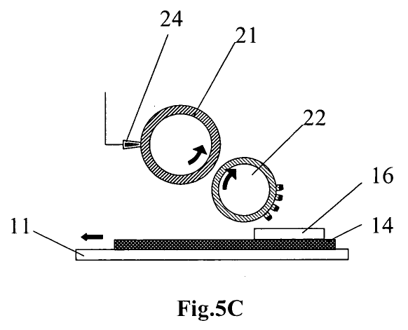

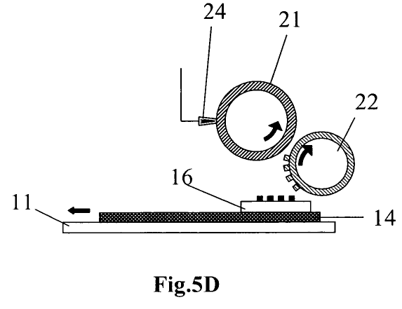

Next, as an example of the printing method that can be used in the present invention, a printing process with a relief printing device is explained in FIGS. 5A-5D in detail.

FIGS. 5A-5D are the schematic views that show a relief printing device and a relief printing process. In FIG. 5, anilox roll 21 and printing cylinder 22 are installed in the upper part of main frame 11. Relief printing plate 23 is mounted around printing cylinder 22. A certain amount of ink is supplied to anilox roll 21 by ink feed means 24. This anilox roll 21 is installed so that the rotating anilox roll 21 touches printing cylinder 22. Anilox roll 21 can supply a certain amount of ink to relief printing plate 23. In addition, substrate 16 on which pixel electrodes are formed is fixed to printing stage 14 at the time of printing. Printing cylinder 22 is installed rotatably. Relief printing plate 23 can touch substrate 16 with constant pressure. In addition, printing stage 14 can move in an uniaxial direction.

Ink 17 is supplied from ink feed means 24 to anilox roll 21. Unnecessary ink is scraped by the doctor blade which is not illustrated. A certain amount of ink is left on an anilox roll (FIG. 5A). Anilox roll 21 that ink 17 has been supplied comes in contact with printing cylinder 22 under rotation. Therefore, ink transfers on a convex part of relief printing plate 23 (FIG. 5B). Then, while printing stage 14 moves, printing cylinder 22 rotates. Therefore, ink pattern transfers on substrate 16 from a convex part of relief printing plate 23. Printing is finished in this way (FIGS. 5C, 5D).

The above-mentioned production process is repeated based on the number of necessary colors. An organic electroluminescent element substrate of the present invention can be manufactured by forming organic light emitting layers of necessary kinds by printing method.

In addition, the wet coat method can be used for formation of layers assisting luminescence such as a hole transport layer or an electron transport layer. For the wet coat method, application methods such as the spin coat method, the die coat method, the dip coat method, the discharge coat method, the precoat method, the roll coat method and the bar coat method, and a printing method such as relief printing and an ink jet printing method can be used. In addition, offset printing may be used.

However, in the case of spin coat method and die coat method, a whole area of a substrate may be covered continuously, domain sectioned by partition wall may be filled up and a layer thicker than needed may be formed. In addition, in the case of an organic electroluminescent element substrate of the present invention, because height of partition wall is low, a layer assisting luminescence may not be sectioned by a partition wall, the layer may be formed on the partition wall, and crosstalk may occur due to short-circuits between adjacent pixels. Therefore, an organic luminescence medium layer such as a hole transport layer other than an organic luminescent layer should be formed by relief printing or offset printing which are good at patterning.

An opposed electrode can be formed next. When an opposed electrode is cathode, the material discussed below can be used.

The material can be of a type with high electron injection efficiency.

In some embodiments, an opposed electrode can include a metal such as Mg, Al, Yb and combination of the same.

In addition, the following layer stack may be put in a boundary surface of the luminescent medium. The layer stack is that with chemical compound of about 1 nm thicknesses such as Li and oxidation Li, LiF and Al and Cu of stability and/or high conductivity. Stability should be balanced with electron injection efficiency. Therefore an alloy system may be used. Alloy of more than one kind of metal such as Li, Mg, Ca, Sr, La, Ce, Er, Eu, Sc, Y. and Yb that have a low work function, and metallic element such as Ag, Al, and Cu which are stable can be used. In some embodiments, alloy such as MgAg, AlLi, and CuLi can be used.

It is desirable to select a material having translucency in so-called top emission construction so as to allow visible radiation to come out of the opposed electrode side. In this case, Li and Ca of a low work function are provided with thin measurements. Metal complex oxide such as ITO (indium tin complex oxide) and indium zinc complex oxide, zinc aluminium complex oxide may be laminated thereafter. In addition, a little metal doping such as Li and Ca of a low work function can be performed to organic luminous layer, and metal compound such as ITO may be laminated.

As formation method of an opposed electrode, according to the material, resistance heating evaporation method, electron-beam evaporation technique, reactive evaporation method, ion plating method and a sputtering method can be used. As for the thickness of an opposed electrode, about 10 nm-1 μm is desirable. The opposed electrode can be patterned if necessary. For example, when organic electroluminescent elements of a passive matrix method are produced, an opposed electrode is formed with pixel electrode in the shape of a stripe, perpendicular to pixel electrode. When an organic electroluminescent element of an active matrix method is produced, an opposed electrode is formed on a whole area of effective picture elements. In addition, in the present invention, a pixel electrode is an anode and an opposed electrode is a cathode, but a pixel electrode may be a cathode and an opposed electrode may be an anode.

A steam barrier layer is formed next. For formation material of a steam barrier layer, metallic oxide and metal nitrides such as silicon oxide, silicon nitride, oxidation silicon nitride, aluminum nitride and aluminium oxide can be used. These materials have an oxygen barrier function other than a steam barrier function. Silicon nitride and oxidation silicon nitride having barrier characteristics, solvent resistance and transparency that are particularly good are desirable. In addition, structure of a barrier layer may be multi-layered structure if necessary.

As a formation method of a steam barrier layer, resistance heating evaporation method, electron-beam evaporation technique, reactivity evaporation method, ion plating method and sputtering method can be used according to the material.

Because difference of height in effective picture elements of an organic electroluminescent element substrate of the present invention is lower than 1 μm, it is not necessary to cover the unevenness by a steam barrier layer, so the thickness of a steam barrier layer may be lower than 0.3 μm. In an organic electroluminescent element of the present invention, it is desirable that film thickness of a steam barrier layer is equal to or less than 0.3 μm more than 0.02 μm. A steam barrier layer cannot carry out a steam barrier function in the case of less than 0.02 μm. In addition, film peeling and a crack occur in a steam barrier layer when a steam barrier layer thickness is more than 0.3 μm.

When barrier layer is made thick, steam barrier property usually improves, while peeling and a crack of barrier layer occur because stress in the layer increases. Therefore, moisture invades inside the organic electroluminescent element substrate. This phenomenon causes deterioration of an organic luminescence medium layer and shortening of life time of the element.

However, a stress can be reduced by confining film thickness of barrier layer to 150 nm in the present invention. Therefore, deterioration of an organic luminescence medium layer and shortening of life time of an element due to peeling and crack of barrier layer, which were a conventional problem, can be solved.

Sealing substrate is pasted by adhesive on a whole area of effective picture elements of an organic electroluminescent element substrate. The sealing substrate should protect the sealing side surface of an organic electroluminescent element substrate and should have transparency. For example, a glass substrate, a glass film, a plastic film or a plastic sheet can be used.

In the case of a taking-up method with the use of a plastic film, an inexpensive element can be obtained. For example, for a plastic, polyethylene terephthalate, polypropylene, cyclo-olefin polymers, a polyamide, polyethersulfone, polymethyl methacrylate and polycarbonate can be used. Barrier layer preventing steam and oxygenic transmission may be formed on the sealing substrate. In particular, when material of the plastic system that steam and oxygen permeate is used as sealing substrate, it is desirable to form a barrier layer.

In the case of an organic electroluminescent element of bottom emission method, sealing substrate does not always need to have transmittance. However, material having transmittance is selected for a sealing substrate when organic electroluminescent element substrate is pasted on a sealing substrate by photo-curing characteristics type adhesive.

Adhesive to paste a sealing substrate on an organic electroluminescent element substrate should have transparency. Well-known adhesive can be used. For example, thermosetting resin and photohardening resin can be used. For example, for thermosetting resin, a melamine system, modacrylic, an epoxy system and urethane system of O⁻ cresol novolac type and bisphenol type can be used. If adhesive is liquid, adhesive is applied to a whole area of effective picture elements of an organic electroluminescent element substrate by the following method: a spin coat method, a bar coat method, a lobe coat method, a dip lotion coat method. And an organic electroluminescent element substrate is pasted on a sealing substrate. In addition, if adhesive is like sheet, adhesive is pasted on sealing substrate by a laminater. As adhesive, both of heat curing type and photo-curing type can be selected. However, it is desirable to select adhesive of photo-curing type to prevent deterioration of an organic luminescent layer. In addition, adhesive can include a desiccating agent and a moisture absorbent to prevent invasion of moisture from an adhesive layer to an organic electroluminescent element.

In addition, an organic electroluminescent element of the present invention may be a flexible substrate by using film material having a flexibility as a substrate and a sealing substrate. In an organic electroluminescent element of the present invention, film thickness of an adhesive layer can be reduced. Therefore, an organic electroluminescent element of the present invention can be a flexible organic electroluminescent element having sufficient flexibility. In addition, film thickness of a steam barrier layer can be reduced. Therefore, as compared to case of a thick steam barrier layer, when a flexible organic electroluminescent element was deflected, a crack is hard to occur in steam barrier layer. Therefore, curvature limit of a flexible organic electroluminescent element can be increased. In addition, the plastic film which is mentioned above can be used preferably as film material for a substrate and a sealing substrate.

In the present invention, difference of height of an organic electroluminescent element substrate is equal to or less than 1 μm. Therefore, the organic electroluminescent element which is not contaminated with air when a sealing substrate is affixed to a whole area of effective pixels of an organic electroluminescent element substrate by adhesive is able to be obtained. Even if a thick adhesive layer and a steam barrier layer are not formed, an organic electroluminescent element with the use of an organic electroluminescent element substrate of the present invention is sealed without air getting around a pixel contributing to display as a display unit. Therefore, when an organic electroluminescent element substrate of the present invention is applied to organic electroluminescent element of top emission type, particularly a good display characteristic can be achieved. In addition, even if sealing is performed under atmospheric pressure, sealing can be performed without air getting in. Therefore, manufacturing process of an organic electroluminescent element can be simplified. In addition, cost can be lowered. Even more particularly, because air does not get into display device, degradation of luminescence property of organic electroluminescent element can be controlled.

### EXAMPLE 1

At first the glass substrate of which thin film transistor corresponding to each picture element was formed was prepared. The ITO of which thickness was 0.1 μm was formed by a sputtering method on a thin film transistor formation side of this glass substrate. Photo resist was applied on ITO formed on a whole area of a glass substrate. It was exposed through a predetermined mask, and it was developed. Pixel electrodes corresponding to thin film transistor were formed by performing wet chemical etching successively.

Subsequently the partition wall of which height was 1.0 μm was formed between pixel electrodes. A partition wall was formed so that the partition wall divided adjacent pixels and covered an edge of each pixel electrode which was patterning in correspondence with thin film transistor. For partition wall material, the novolac resin which was a light-sensitive resin was used. Novolac resin was applied to all over pixel electrodes. It was exposed through a predetermined mask. Subsequently pattern formation was performed by developing.

The organic luminescence medium layer was formed on pixel electrodes sectioned by a partition wall. The organic luminescence medium layer included a hole transport layer that was common to all picture element, and an organic luminescent layer emitting light with a prescribed color. The poly tetrahydro thiophenyl phenylene which was a polymer precursor was used as a hole injection material. A water solution of this material was applied by a spin coat method to pixel electrodes sectioned by a partition wall. By heating, the precursor became polyphenylene vinylene. The hole injection layer of which thickness was 0.05 μm was formed on each pixel electrode in this way.

Cyano polyphenylene vinylene was used as red luminescence material. Polyphenylene vinylene was used as green emission material. Polyphenylene vinylene was used as blue luminescence material. Luminescent material ink of each color was made by dissolving these organic luminescent materials in a toluene. Successively luminescent material inks of red, a green and blue were printed on a hole transport layer by a letterpress reverse offset printing. The organic luminescent layer of which thickness was 0.05 μm was formed in this way. In addition, arrangement of picture elements formed here was arrangement of form of stripe where picture elements emitting the same color light were arranged linearly.

Next, as an opposed electrode, MgAg of which thickness was 0.01 μm was formed on a whole area of an organic luminescence medium layer by evaporation method. The ITO of which thickness was 0.1 μm was further formed by sputter method. An organic electroluminescent element substrate was made in this way. The unevenness in effective picture elements of an organic electroluminescent element substrate obtained in this way was about 0.7 μm.

Next, as a steam barrier layer, the silicon oxide of which thickness was 0.1 μm was formed on an organic electroluminescent element substrate by evaporation method. Thereupon, using the sheet epoxy adhesive of which thickness was 30 μm, glass plate was put by a laminater. And it was heated. A top emission type organic electroluminescent element of an active matrix method was obtained in this way.

An obtained organic electroluminescent element was observed by microscope. However, the state that air was mixed was not observed in a region of effective picture elements of an organic electroluminescent element. In addition, the color mixture with adjacent pixel was not observed.

### EXAMPLE 2

The ITO of which thickness was 0.1 μm was formed by a sputtering method on silicon oxide film face on a polyethylene terephthalate (PET) film on which silicon oxide film was formed beforehand. Photo resist was applied. Exposure/developing were performed. Successively stripe pixel electrodes were formed by performing wet chemical etching. The line width of line patterns of the ITO which was pixel electrodes was 100 μm. The space of the line patterns was 50 μm. The number of lines of the line patterns was 192.

Subsequently a partition wall was formed in the shape of a line in parallel with first electrode between pixel electrodes to cover an edge of line-shaped pixel electrodes. The partition wall height was 0.8 μm. For partition wall material, the novolac resin which was a light-sensitive resin was used. Pattern formation was performed by exposure/developing.

Next, as a hole injection material, the poly tetrahydro thiophenyl phenylene which was a polymer precursor was formed by a spin coat method. By heating, the precursor became polyphenylene vinylene. The hole injection layer of which thickness was 0.05 μm was formed in this way.

Cyano polyphenylene vinylene was used as a red luminescence material. Polyphenylene vinylene was used as a green emission material. Polyphenylene vinylene and poly alkyl phenylene were used as a blue luminescence material. Ink of each color was made by dissolving these organic luminescent materials in a toluene. Successively, inks of red, green and blue were printed on line-shaped pixel electrodes by relief printing. The organic luminescent layer of which thickness was 0.05 μm was formed in this way.

Next, pattern of MgAg of which thickness was 0.01 μm was formed as an opposed electrode by evaporation method using a mask. Pattern of the ITO of which thickness was 0.1 μm was further formed on MgAg by sputter method using a mask. The opposed electrode comprising MgAg and ITO was formed to be perpendicular to line-shaped pixel electrodes. The unevenness in effective picture elements was about 0.5 μm.

Next, the silicon oxide of which thickness was 0.1 μm was formed by evaporation method as a steam barrier layer on an organic electroluminescent element substrate. Thereupon, polyethylene terephthalate (PET) was put by a laminater using the sheet epoxy adhesive of which thickness was 30 μm. This object was heated. A top emission type flexible organic electroluminescent element of a passive matrix method was obtained.

An obtained organic electroluminescent element was observed by microscope. A state that air was mixed in an organic electroluminescent element was not observed. In addition, good luminescence was obtained when an obtained organic electroluminescent element emitted light. In addition, the obtained organic electroluminescent element had a flexibility.

### COMPARATIVE EXAMPLE

The partition wall of which height was 2.0 μm was made. An element was made same as example 2 other than the height of the partition wall. The difference of height in picture elements was about 1.7 μm. An obtained organic electroluminescent element was observed by microscope. A state that bubbles were contained in an organic electroluminescent element was confirmed.

What is claimed is:

1. An organic electroluminescent element substrate, comprising: a substrate, pixel electrodes disposed over the substrate, an organic luminescence medium layer including an organic luminescent layer disposed over the pixel electrodes which emits different color light, and opposed electrodes, wherein the organic luminescence medium layer is between the pixel electrodes and the opposed electrodes,
wherein the organic electroluminescent element substrate has partition wall(s), and
wherein difference of height in effective pixels of the organic electroluminescent element substrate is less than 1 μm.

2. An organic electroluminescent element which is manufactured by pasting the organic electroluminescent element substrate according to claim 1 on a sealing substrate by an adhesive,
wherein the adhesive covers a whole area of the effective pixels.

3. An organic electroluminescent element according to claim 2,
wherein a steam barrier layer is formed on the organic electroluminescent element, and
wherein the organic electroluminescent element including the steam barrier layer is pasted on the sealing substrate by the adhesive.

4. An organic electroluminescent element according to claim 3,
wherein thickness of the steam barrier layer is 0.02 μm-0.3 μm.

5. The organic electroluminescent element of claim 2, wherein the substrate comprises a flexible film.

6. A manufacturing method of the organic electroluminescent element substrate according to claim 1,
said method includes
making ink by dissolving an organic luminescent material, a hole transport material, an electron block material or an electron injection material in a solvent, and
forming an organic luminescent media layer by printing the ink.
